(19) United States
(12) Patent Application Publication
(10) Pub. No.: US 2017/0287928 A1
(43) Pub. Date: Oct. 5, 2017

(54) SEMICONDUCTOR MEMORY DEVICES

(71) Applicants: Kohji KANAMORI, Seoul (KR); Shinhwan KANG, Seoul (KR); Kwang-Soo KIM, Hwaseong-si (KR); Youngwoo PARK, Seoul (KR); Chadong YEO, Suwon-si (KR); Jaegoo LEE, Suwon-si (KR)

(72) Inventors: Kohji KANAMORI, Seoul (KR); Shinhwan KANG, Seoul (KR); Kwang-Soo KIM, Hwaseong-si (KR); Youngwoo PARK, Seoul (KR); Chadong YEO, Suwon-si (KR); Jaegoo LEE, Suwon-si (KR)

(21) Appl. No.: 15/430,879

(22) Filed: Feb. 13, 2017

(30) Foreign Application Priority Data
Apr. 4, 2016 (KR) 10-2016-0041231

(51) Int. Cl. H01L 27/11582; H01L 23/528; G11C 5/06; H01L 27/11565

(52) U.S. Cl. CPC H01L 27/11582; H01L 27/11565; H01L 23/528; G11C 5/063

(57) ABSTRACT

Semiconductor devices are provided. Semiconductor devices may include a stack structure including word lines stacked on a substrate, first vertical pillars and second vertical pillars that extend through the stack structure, a first string select line overlapping the first vertical pillars in a plan view, and a second string select line overlapping the second vertical pillars in the plan view and being spaced apart from the first string select line in a first direction. In a plan view, a shortest distance between a side of one of the first vertical pillars and a side of one of the second vertical pillars is less than a shortest distance between a side of the first string select line and a side of the second string select line.

### CROSS-REFERENCE TO RELATED APPLICATION

This U.S. nonprovisional patent application claims priority under 35 U.S.C. §119 to Korean Patent Application 10-2016-0041231, filed on Apr. 4, 2016, the disclosure of which is hereby incorporated by reference in its entirety.

### BACKGROUND

The present disclosure relates to the field of electronics and, more particularly, to a semiconductor memory device.

Semiconductor devices have been highly integrated in an attempt to provide high performance and low manufacturing cost. Since integration density of semiconductor devices may be a factor in determining product price, highly integrated semiconductor devices have been increasingly demanded. Integration density of typical two-dimensional or planar semiconductor devices may be determined by the surface area occupied by a unit memory cell, such that it may be influenced by technology for forming fine patterns. However, expensive equipment may be used to form fine patterns, and thus increased the integration density of the two-dimensional or planar semiconductor devices may be limited. Three-dimensional semiconductor memory devices having three-dimensionally arranged memory cells have been proposed to further increase integration density.

### SUMMARY

Embodiments of the present inventive concept provide a semiconductor memory device having a high integration density.

According to example embodiments of the present inventive concepts, a semiconductor memory device may include a stack structure including word lines stacked on a substrate, first vertical pillars and second vertical pillars that extend through the stack structure, a first string select line overlapping the first vertical pillars in a plan view, and a second string select line overlapping the second vertical pillars in the plan view and being spaced apart from the first string select line in a first direction. In the plan view, a shortest distance between a side of one of the first vertical pillars and one of the second vertical pillars that is closest to the one of the first vertical pillars may be less than a shortest distance between a side of the first string select line and a side of the second string select line.

According to example embodiments of the present inventive concepts, a semiconductor memory device may include a stack structure including word lines stacked on a substrate, first vertical pillars and second vertical pillars that extend through the stack structures, a first string select line overlapping the first vertical pillars in a plan view, and a second string select line overlapping the second vertical pillars in the plan view and being horizontally spaced apart from the first string select line. In the plan view, at least one of the first and second vertical pillars may be overlapped by an area between the first and second string select lines.

According to example embodiments of the present inventive concepts, an integrated circuit device may include a stack structure including a plurality of word lines stacked on a substrate, a first vertical pillar extending through the stack structure and a first string select line overlapping the first vertical pillar in a plan view and extending longitudinally in a first direction. The first string select line may include a first sidewall and a second sidewall opposite the first sidewall, and the first vertical pillar may be closer to the first sidewall of the first string select line than the second sidewall of the first string select line. The integrated circuit device may include a first string channel pillar extending through the first string select line and being electrically connected to the first vertical pillar. A center of the first string channel pillar may be offset from a center of the first vertical pillar in a second direction, which traverses the first direction, away from the first sidewall of the first string select line in the plan view.

### BRIEF DESCRIPTION OF THE DRAWINGS

FIG. 1 is a schematic circuit diagram of a cell array of a semiconductor memory device according to example embodiments of the present inventive concepts.

FIGS. 2A and 2B are plan views illustrating a semiconductor memory device according to example embodiments of the present inventive concepts.

FIG. 3 is a cross-sectional view, taken along the line I-I′ of FIGS. 2A and 2B, according to example embodiments of the present inventive concepts.

FIG. 4 is an enlarged view of the section A in FIG. 3.

FIGS. 5A and 5B are enlarged views illustrating the first and second vertical pillars, the first and second string select lines, and first and second string channel pillars according to example embodiments of the present inventive concepts.

FIG. 6 is a cross-sectional view, taken along the line I-I′ of FIGS. 2A and 2B, according to example embodiments of the present inventive concepts.

FIG. 7 is a cross-sectional view, taken along the line I-I′ of FIGS. 2A and 2B, according to example embodiments of the present inventive concepts.

FIGS. 8A and 8B are plan views illustrating a semiconductor memory device according to example embodiments of the present inventive concepts.

FIG. 9 is a cross-sectional view, taken along the line I-I′ of FIGS. 8A and 8B, according to example embodiments of the present inventive concepts.

FIG. 10 is a cross-sectional view illustrating a semiconductor memory device according to example embodiments of the present inventive concepts.

FIGS. 11A to 11J are cross-sectional views, taken along the line I-I′ of FIGS. 2A and 2B, illustrating a method of fabricating a semiconductor memory device according to example embodiments of the present inventive concepts.

### DETAILED DESCRIPTION OF EMBODIMENTS

As used herein the term “and/or” includes any and all combinations of one or more of the associated listed items. It will be understood that references herein to “an element A vertically overlapping an element B” (or similar language) means that a vertical line, which intersects both the elements A and B, exists.

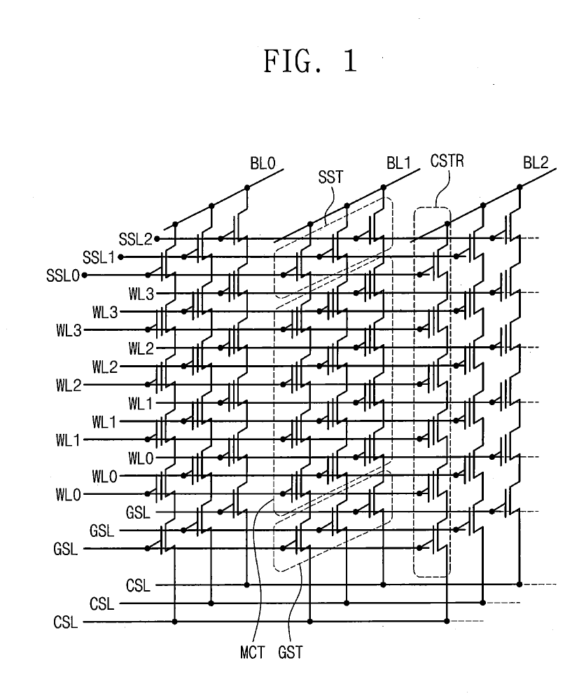

FIG. 1 is a schematic circuit diagram of a cell array of a semiconductor memory device according to example embodiments of the present inventive concepts.

Referring to FIG. 1, a semiconductor memory device according to example embodiments may include a common source line CSL, a plurality of bit lines BL0 to BL2, and a plurality of cell strings CSTR disposed between the common source line CSL and the bit lines BL0 to BL2.

The bit lines BL0 to BL2 may be two-dimensionally arranged, and the plurality of cell strings CSTR may be connected in parallel to each of the bit lines BL0 to BL2. Thus, the cell strings CSTR may be two-dimensionally arranged on either the common source line CSL or a substrate.

Each of the cell strings CSTR may include a ground select transistor GST connected to the common source line CSL, a string select transistor SST connected to one of the bit lines BL0 to BL2, and a plurality of memory cell transistors MCT disposed between the ground select transistor GST and string select transistor SST. The ground select transistor GST, the string select transistor SST, and the memory cell transistors MCT may be connected in series. In addition, a ground select line GSL, a plurality of word lines WL0 to WL3, and a plurality of string select lines SSL0 to SSL2 disposed between the common source line CSL and the bit lines BL0 to BL2 may be respectively used as gate electrodes of the ground select transistor GST, the memory cell transistors MCT, and the string select transistor SST.

The gate electrodes of the ground select transistor GST may be commonly connected to the ground select line GSL and thereby may have the same electrical potential state. Similarly, the gate electrodes of the plurality of memory cell transistors MCT, which are located at the same distance from the common source line CSL, may also be commonly connected to one of the word lines WL0 to WL3 to have the same electrical potential state. On the other hand, as one cell string CSTR includes a plurality of memory cell transistors MCT that are disposed at different distances from the common source line CSL, the word lines WL0 to WL3 may be disposed to have a multi-layered structure between the common source line CSL and the bit lines BL0 to BL2.

The ground and string select transistors GST and SST and the memory cell transistors MCT may be a metal-oxide-semiconductor field effect transistor (MOSFET) using a channel structure as a channel region. In some embodiments, the channel structure may constitute a MOS capacitor together with the ground select line GSL, the word lines WL0 to WL3, and the string select lines SSL. In this case, the ground select transistor GST, the memory cell transistors MCT, and the string select transistor SST may be electrically connected to each other by sharing inversion layers formed by a fringe field from the ground select line GSL, the word lines WL0 to WL3, and the string select lines SSL.

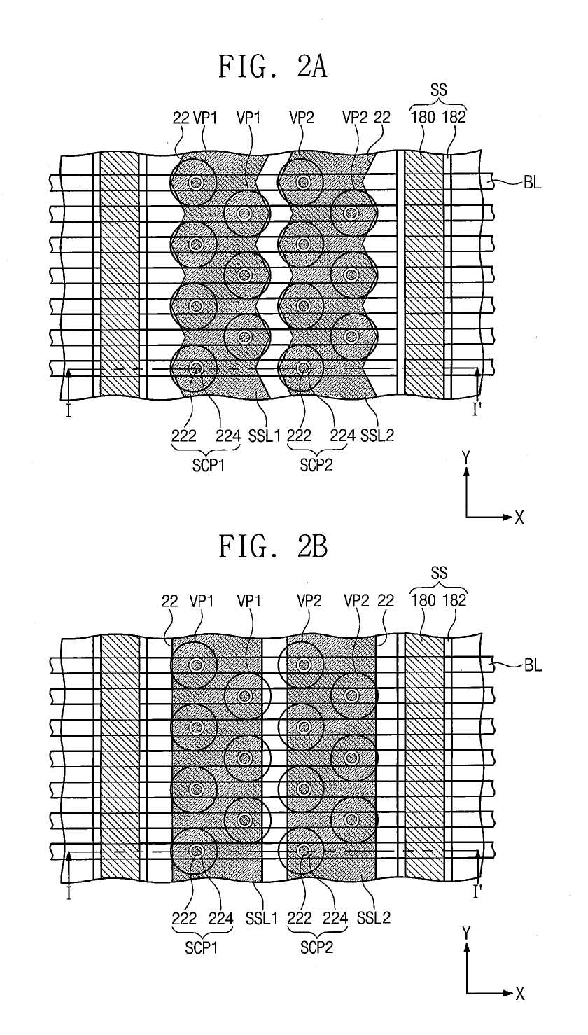

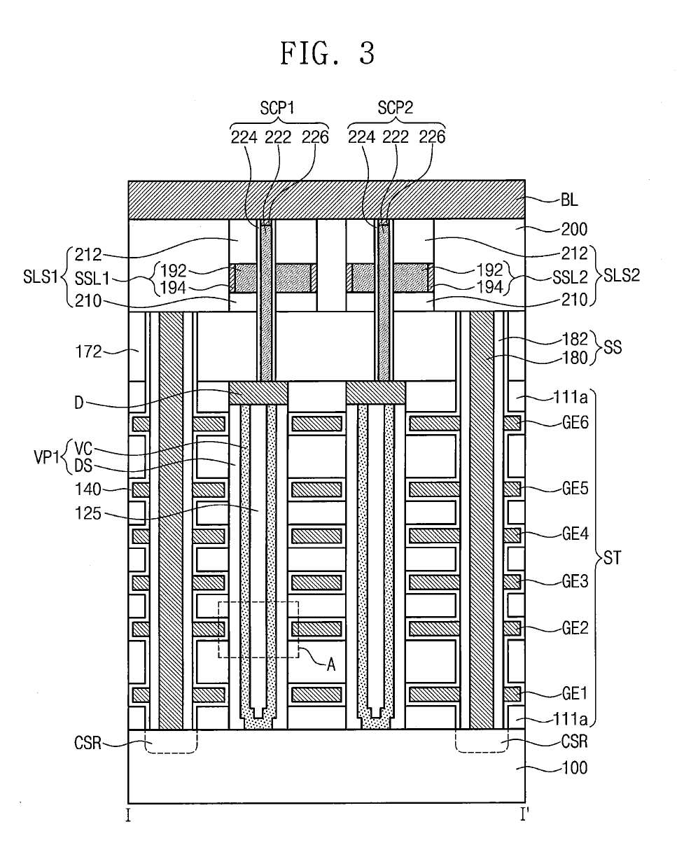

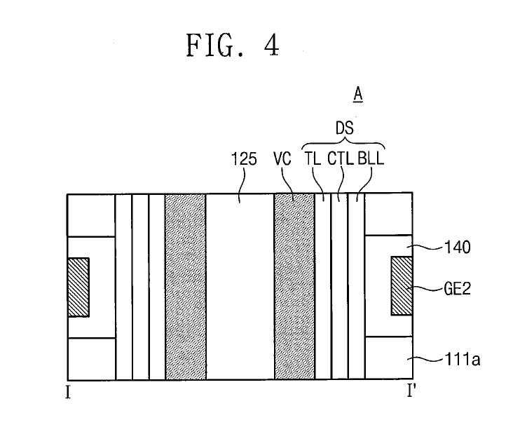

FIGS. 2A and 2B are plan views illustrating a semiconductor memory device according to example embodiments of the present inventive concepts. FIG. 3 is a cross-sectional view, taken along the line I-P of FIGS. 2A and 2B, according to example embodiments of the present inventive concepts. FIG. 4 is an enlarged view of the section A in FIG. 3.

Referring to FIGS. 2A, 2B and 3, a plurality of stack structures ST may be disposed on a substrate 100. The substrate 100 may be a silicon substrate, a silicon-germanium substrate, a germanium substrate, or a single crystalline epitaxial layer grown on a single crystalline silicon substrate. The plurality of stack structures ST may be spaced apart from each other in a first direction X and extend in a second direction Y traversing (e.g., crossing) the first direction X. An impurity region CSR may be disposed in the substrate 100 between the stack structures ST. The impurity region CSR may extend in the second direction Y. The impurity region CSR may correspond to the common source line CSL depicted in FIG. 1. In this case, the impurity region CSR may have a different conductivity from the substrate 100.

Each of the stack structures ST may include insulation patterns 111a and first to sixth gate electrodes GE1 to GE6. The first to sixth gate electrodes GE1 to GE6 may be sequentially stacked on the substrate 100 in a direction that is perpendicular to a top surface of the substrate 100. The insulation patterns 111a may be disposed between the first to sixth gate electrodes GE1 to GE6. The first gate electrode GE1, i.e., a lowermost gate may be a gate of a ground select transistor and correspond to the ground select line GSL of FIG. 1. The second to sixth gate electrodes GE2 to GE6 disposed between the first gate electrode GE1 and an uppermost insulation pattern 111a may be cell gate electrodes corresponding to the word lines WL0 to WL3 of FIG. 1. The insulation patterns 111a may include, for example, a silicon oxide layer. The first to sixth gate electrodes GE1 to GE6 may include doped silicon, metal (e.g., tungsten), metal nitride, metal silicide, or a combination thereof.

Vertical pillars VP1 and VP2 may respectively penetrate the stack structures ST. In some embodiments, the vertical pillars VP1 and VP2 may be arranged in a zig-zag pattern in the second direction Y as illustrated in FIGS. 2A and 2B. For example, the vertical pillars VP1 and VP2 may include first vertical pillars VP1 and second vertical pillars VP2. Each of the vertical pillars VP1 and VP2 may include a vertical channel section VC and a charge storage structure DS. The vertical channel section VC may penetrate the stack structure ST in a direction that is perpendicular to the top surface of the substrate 100 and may be electrically connected to the substrate 100. The vertical channel section VC may contact the top surface of the substrate 100. The vertical channel section VC may include a shape of hollow pipe, cylinder, or cup. The vertical channel section VC may include a semiconductor material. For example, the vertical channel section VC may be one of a polycrystalline silicon layer, an organic semiconductor layer, and carbon nano structures.

The charge storage structure DS may be disposed between the vertical channel section VC and the first to sixth gate electrodes GE1 to GE6. In detail, the charge storage structure DS may be disposed between the vertical channel section VC and each of the first to sixth gate electrodes GE1 to GE6 and extend in a vertical direction along a sidewall of the vertical channel section VC. In a plan view, the charge storage structure DS may have a shape that surrounds an outer sidewall of the vertical channel section VC.

As shown in FIG. 4, the charge storage structure DS may include a tunneling insulation layer TL, a charge storage layer CTL, and a blocking insulation layer BLL. The tunneling insulation layer TL may be disposed between the vertical channel section VC and the stack structure ST. The blocking insulation layer BLL may be disposed between the tunneling insulation layer TL and the stack structure ST. The charge storage layer CTL may be disposed between the tunneling insulation layer TL and the blocking insulation layer BLL. The tunneling insulation layer TL may include, for example, a silicon oxide layer or a high-k dielectric layer (e.g., aluminum oxide (Al₂O₃), hafnium oxide (HfO₂), etc.), the charge storage layer CTL may include a silicon nitride layer, and the blocking insulation layer BLL may include a silicon oxide layer or a high-k dielectric layer (e.g., aluminum oxide (Al₂O₃), hafnium oxide (HfO₂), etc.).

A gap-fill layer 125 may be disposed in an inner space surrounded by the vertical channel section VC. The gap-fill layer 125 may include an insulating material, for example, a silicon oxide layer, a silicon nitride layer, and/or a silicon oxynitride layer. Pads D may be disposed on upper portions of the vertical pillars VP1 and VP2. Each of the pads D may be electrically connected to the vertical channel section VC. The pads D may include a conductive material or a semiconductor material which is doped with impurities that have a different conductivity from the vertical channel section VC.

A horizontal insulation layer 140 may be disposed between the charge storage structure DS and each of the first to sixth gate electrodes GE1 to GE6. The horizontal insulation layer 140 may extend onto top and bottom surfaces of each of the first to sixth gate electrodes GE1 to GE6. The horizontal insulation layer 140 may include, for example, a silicon oxide layer (e.g., SiO₂) or a high-k dielectric layer (e.g., aluminum oxide (Al₂O₃), hafnium oxide (HfO₂), etc.).

First interlayer dielectric layers 172 may be disposed on the stack structures ST. In detail, each of the first interlayer dielectric layers 172 may be disposed on a top surface of the uppermost insulation pattern 111a and top surfaces of the pads D. The first interlayer dielectric layers 172 may include, for example, a silicon oxide layer and/or a silicon nitride layer.

A separation structure SS may be disposed between the stack structures ST and between the first interlayer dielectric layers 172. The separation structure SS may be disposed on the impurity region CSR and may extend in the second direction Y along the impurity region CSR. The separation structure SS may have a shape of rectangle or line extending in the second direction Y. The separation structure SS may include a common source contact 180 and spacers 182. Each of the spacers 182 may be disposed between the common source contact 180 and the stack structure ST and between the common source contact 180 and the first interlayer dielectric layer 172. In other words, the common source contact 180 may be disposed between the spacers 182. The common source contact 180 may be electrically connected to the impurity region CSR. The common source contact 180 may include, for example, a conductive material (e.g., a silicon layer, a metal layer, or a silicide layer). The spacers 182 may include, for example, an insulating material (e.g., a silicon oxide layer, a silicon nitride layer, etc.).

A first string select structure SLS1 and a second string select structure SLS2 on the stack structure ST. The first and second string select structures SLS1 and SLS2 may be spaced apart from each other in the first direction X while extending in the second direction Y. In a plan view, the first string select structure SLS1 may vertically overlap the first vertical pillars VP1, and the second string select structure SLS2 may vertically overlap the second vertical pillars VP2. The first string select structure SLS1 may include a first insulation pattern 210, a first string select line SSL1, and a second insulation pattern 212 that are sequentially stacked on the first interlayer dielectric layer 172. The second string select structure SLS2 may include a first insulation pattern 210, a first string select line SSL1, and a second insulation pattern 212 that are sequentially stacked on the first interlayer dielectric layer 172. The first and second insulation patterns 210 and 212 may include an insulating material (e.g., a silicon oxide layer, a silicon nitride layer, etc.).

Each of the first and second string select lines SSL1 and SSL2 may be disposed between the first and second insulation patterns 210 and 212. The first and second string select lines SSL1 and SSL2 may be gate electrodes of string select transistors and correspond to the string select lines SSL0 to SSL2 of FIG. 1. Each of the first and second string select lines SSL1 and SSL2 may include a first conductive pattern 192 and a second conductive pattern 194. The first conductive pattern 192 may have a shape of line or rectangle extending in the second direction Y. Each of the second conductive patterns 194 may be disposed on sidewalls of the first conductive pattern 192. That is, the first conductive pattern 192 may be disposed between the second conductive patterns 194. The first conductive pattern 192 may include, for example, polysilicon. The second conductive patterns 194 may include a metal silicide material. FIG. 2B has a structure substantially the same as or similar to that of FIG. 2A except shapes of the first and second string select lines SSL1 and SSL2. In some embodiments, sides of the first and second string select lines SSL1 and SSL2 may be straight as illustrated in FIG. 2B.

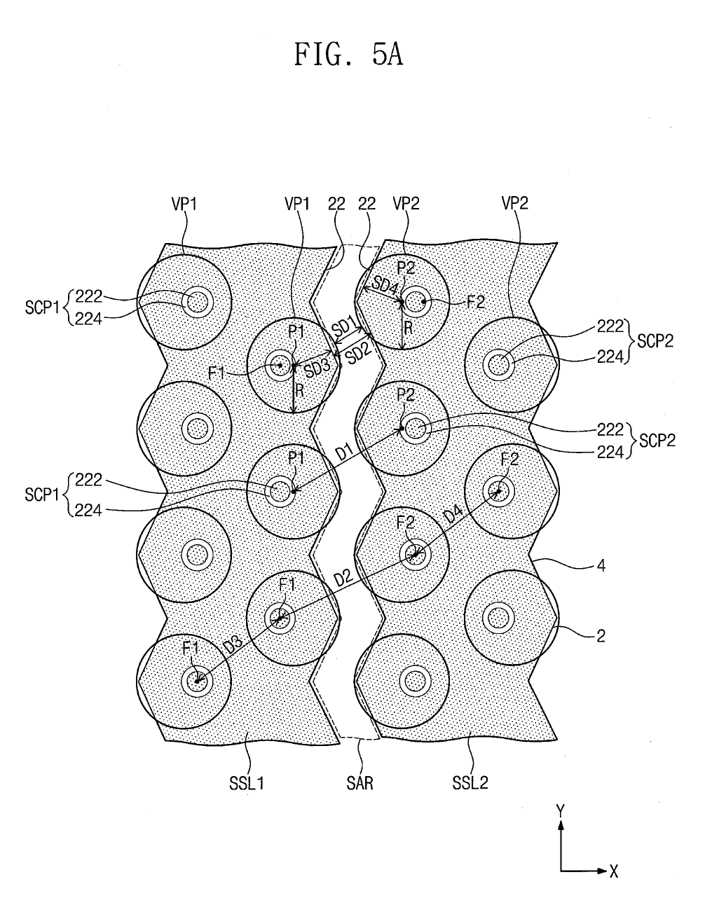

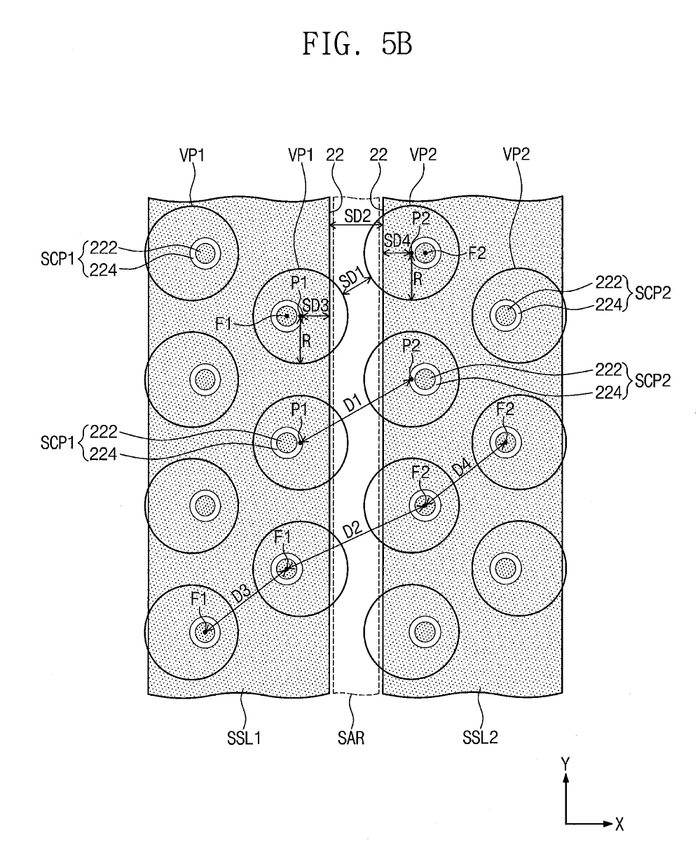

FIG. 5A is an enlarged view illustrating the first and second vertical pillars VP1 and VP2, the first and second string select lines SSL1 and SSL2, and first and second string channel pillars SCP1 and SCP2 according to example embodiments of the present inventive concepts. FIG. 5A is an enlarged plan view of a portion of FIG. 2A.

Referring to FIGS. 2A and 5A, in a plan view, each of the first and second string select lines SSL1 and SSL2 may include protrusions 2 and recesses 4. For example, in a plan view, the recesses 4 may be disposed between the first vertical pillars VP1 adjacent to each other in the second direction Y and between the second vertical pillars VP2 adjacent to each other in the second direction Y. The protrusions 2 may be disposed between the recesses 4 adjacent to each other in the second direction Y. For example, the protrusion 2 of the first string select line SSL1 and the recess 4 of the second string select line SSL2 may be adjacent to each other in the first direction X, and the recess 4 of the first string select line SSL1 and the protrusion 2 of the second string select line SSL2 may be adjacent to each other in the first direction X.

FIG. 5B is an enlarged view illustrating the first and second vertical pillars VP1 and VP2, the first and second string select lines SSL1 and SSL2, and first and second string channel pillars SCP1 and SCP2 according to example embodiments of the present inventive concepts. FIG. 5B is an enlarged plan view of a portion of FIG. 2B.

Referring to FIGS. 2B and 5B, in a plan view, each of the first and second string select lines SSL1 and SSL2 may have a straight line shape extending in the second direction Y.

An arrangement relationship between the first and second vertical pillars VP1 and VP2 and the first and second string select lines SSL1 and SSL2 will be hereinafter discussed with reference to FIGS. 5A and 5B.

Referring to FIGS. 5A and 5B, in a plan view, a minimum (e.g., shortest) distance SD1 between the first and second vertical pillars VP1 and VP2 may be less than a minimum (e.g., shortest) distance SD2 between the first and second string select lines SSL1 and SSL2. For example, in a plan view, a minimum (e.g., shortest) distance SD3 between a side surface 22 of the first string select line SSL1 and a center P1 of each of the first vertical pillars VP1 may be less than a radius R of the first vertical pillar VP1. Similarly, in a plan view, a minimum (e.g., shortest) distance SD4 between a side surface 22 of the second string select line SSL2 and a center P2 of each of the second vertical pillars VP2 may be less than a radius R of the second vertical pillar VP2.

In a plan view, at least one of the first and second vertical pillars VP1 and VP2 may have a portion that adjoins and vertically overlaps an area SAR between the first and second string select lines SSL1 and SSL2. For example, as shown in FIGS. 5A and 5B, each of the first and second vertical pillars VP1 and VP2 may have a portion that is adjacent to and vertically overlaps the area SAR, in a plan view.

Referring again to FIGS. 2A, 2B and 3, first string channel pillars SCP1 and second string channel pillars SCP2 may be provided to penetrate the first string select structure SLS1 and the second string select structure SLS2, respectively. Each of the first string channel pillars SCP1 may be electrically connected to each of the first vertical pillars VP1, and each of the second string channel pillars SCP2 may be electrically connected to each of the second vertical pillars VP2. Each of the first and second string channel pillars SCP1 and SCP2 may be in contact with a respective one of the pads D.

Each of the first and second string channel pillars SCP1 and SCP2 may include a string vertical channel section 222, a string vertical insulation layer 224, and a string conductive pattern 226. The pad D may be in contact with the string vertical channel section 222 penetrating the first interlayer dielectric layer 172 and one of the first and second string select structures SLS1 and SLS2. For example, the string vertical channel section 222 may have a cylindrical shape. The string vertical channel section 222 may be, for example, one of a polycrystalline silicon layer, an organic semiconductor layer, and carbon nanostructures.

The string vertical insulation layer 224 may be disposed between the string vertical channel section 222 and one of the first and second string select lines SSL1 and SSL2, and extend in a vertical direction along an outer wall of the string vertical channel section 222. For example, the string vertical insulation layer 224 may surround the outer wall of the string vertical channel section 222. The string vertical insulation layer 224 may include, for example, a silicon oxide layer, a silicon nitride layer, or a high-k dielectric layer (e.g., aluminum oxide (Al₂O₃), hafnium oxide (HfO₂), etc.).

The string conductive pattern 226 may be disposed on an upper portion of the string vertical channel section 222. The string conductive pattern 226 may include, for example, a metal silicide material.

An arrangement relationship between the first and second string channel pillars SCP1 and SCP2 will be discussed with reference to FIGS. 5A and 5B.

Referring again to FIGS. 5A and 5B, diameters of the first and second vertical pillars VP1 and VP2 may be greater than diameters of the first and second string channel pillars SCP1 and SCP2. In a plan view, centers F1 of the first string channel pillars SCP1 may be offset from the centers P1 of the first vertical pillars VP1. Similarly, in a plan view, centers F2 of the second string channel pillars SCP2 may be offset from the centers P2 of the second vertical pillars VP2. For example, a minimum (e.g., shortest) distance D1 between the centers P1 and P2 of the first and second vertical pillars VP1 and VP2 adjacent to each other may be less than a minimum (e.g., shortest) distance D2 between the centers F1 and F2 of the first and second string channel pillars SCP1 and SCP2 adjacent to each other. In this case, the minimum distance D1 between the centers P1 and P2 of the first and second vertical pillars VP1 and VP2 adjacent to each other may be substantially the same as a minimum (e.g., shortest) distance between the centers P1 of adjacent first vertical pillars VP1 and a minimum (e.g., shortest) distance between the centers P2 of adjacent second vertical pillars VP2.

The minimum distance D2 between the centers F1 and F2 of the first and second string channel pillars SCP1 and SCP2 adjacent to each other may be greater than a minimum (e.g., shortest) distance D3 between the centers F1 of adjacent first string select channel pillars SCP1 and than a minimum (e.g., shortest) distance D4 between the centers F2 of adjacent second select channel pillars SCP2.

In some embodiments, the center F1 of each of the first string channel pillars SCP1 may be offset from the center P1 of the corresponding one of the first vertical pillars VP1 in the first direction X away from one of opposing sidewalls of the first string select line SSL1 that is the closet to the corresponding one of the first vertical pillars VP1 as illustrated in FIGS. 5A and 5B. The center F2 of each of the second string channel pillars SCP2 may be offset from the center P2 of the corresponding one of the second vertical pillars VP2 in the first direction X from one of opposing sidewalls of the second string select line SSL2 that is the closet to the corresponding one of the second vertical pillars VP2 as illustrated in FIGS. 5A and 5B.

According to example embodiments of the present inventive concepts, a plurality of the string select lines SSL1 and SSL2 may be disposed horizontally spaced apart from each other on the stack structure ST such that it may be possible to secure a patterning space between the first and second string select lines SSL1 and SSL2 without limitation of a minimum spaced distance between the first and second vertical pillars VP1 and VP2. It thus may be advantageous to enhance an integration of semiconductor memory cells without increasing an area of the stack structure ST.

Referring again to FIGS. 2A, 2B and 3, bit lines BL may be disposed on the first and second string select structures SLS1 and SLS2. The bit lines BL may extend in the first direction X and may traverse the stack structures ST. Each of the bit lines BL may be electrically connected to one of the first vertical pillars VP1 through one of the first string channel pillars SCP1 and may be electrically connected to one of the second vertical pillars VP2 through one of the second string channel pillars SCP2. For example, the bit lines BL may be in contact with the string conductive patterns 226. The bit lines BL may include a metallic material (e.g., tungsten).

A second interlayer dielectric layer 200 may be disposed between the bit lines BL and the stack structures ST. The second interlayer dielectric layer 200 may be interposed between the first and second string select structures SLS1 and SLS2. For example, the second interlayer dielectric layer 200 may be in contact with the second conductive patterns 194. The second interlayer dielectric layer 200 may include an insulating material (e.g., a silicon oxide layer, a silicon nitride layer, etc.).

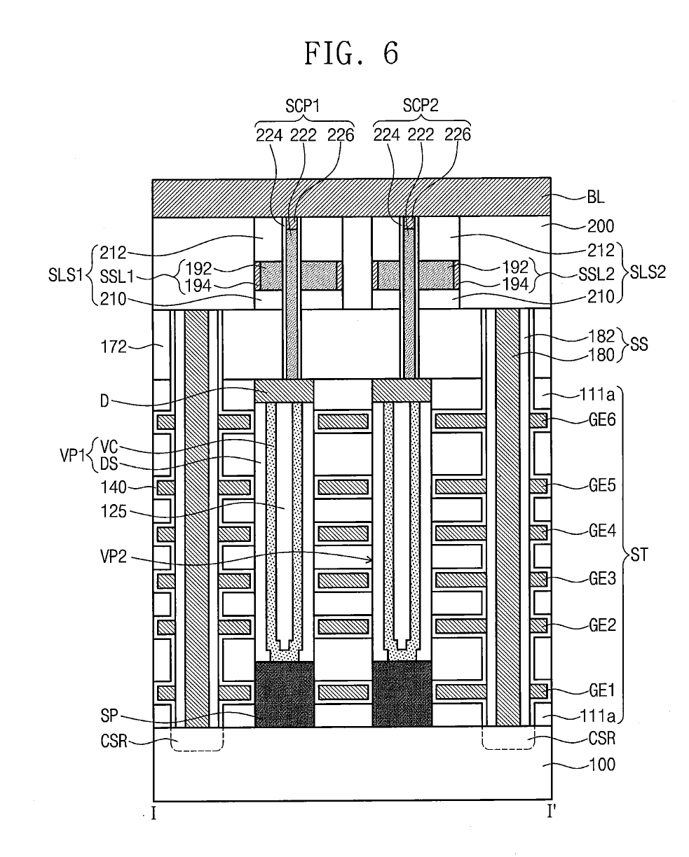

FIG. 6 is a cross-sectional view, taken along the line of FIGS. 2A and 2B, according to example embodiments of the present inventive concepts. Like reference numbers refer to like elements throughout. For brevity of the description, discussions of those components of the semiconductor memory device that have been already discussed may be omitted.

Referring to FIG. 6, a semiconductor pillar SP may be disposed between the substrate 100 and each of the vertical channel sections VC. The semiconductor pillar SP may be disposed on the top surface of the substrate 100 and penetrate the first gate electrode GE1 and the lowermost insulation pattern 111a. The vertical channel section VC may be in contact with and electrically connected to the semiconductor pillar SP. The semiconductor pillar SP may be either an intrinsic semiconductor or a semiconductor having the same conductivity as that of the substrate 100. For example, the semiconductor pillar SP may be either a single crystalline intrinsic semiconductor or a p-type conductive semiconductor.

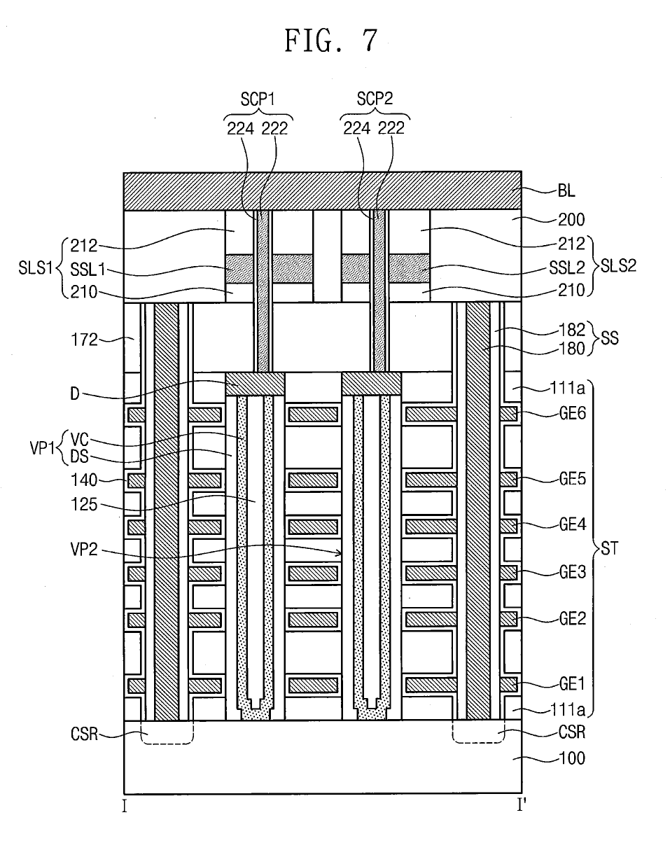

FIG. 7 is a cross-sectional view, taken along the line I-I′ of FIGS. 2A and 2B, according to example embodiments of the present inventive concepts. For brevity of the description, discussions of those components of the semiconductor memory device that have been already discussed may be omitted.

Referring to FIG. 7, each of the first and second string select lines SSL1 and SSL2 may be a single layer. Each of the first and second string select lines SSL1 and SSL2 may include, for example, a polysilicon layer. In other words, unlike the semiconductor memory device illustrated in FIG. 3, the first and second string select lines SSL1 and SSL2 may not include second conductive patterns 194.

Each of the first and second string channel pillars SCP1 and SCP2 may include the string vertical channel section 222 and the string vertical insulation layer 224. For example, the string vertical channel section 222 may be in contact with each of the bit lines BL. In other words, unlike the semiconductor memory device illustrated in FIG. 3, the string conductive pattern 226 may not be disposed on the upper portion of the string vertical channel section 222.

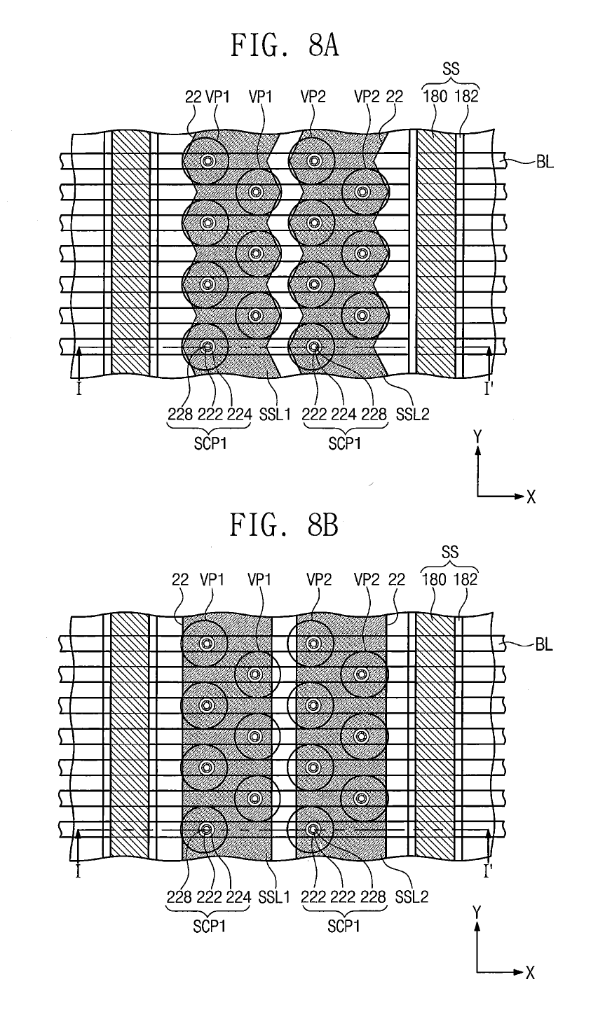

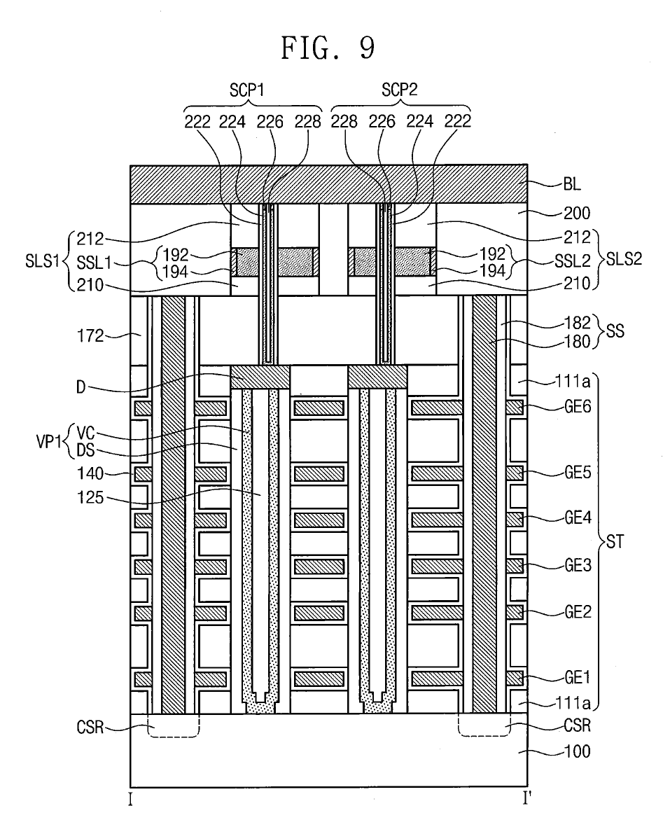

FIGS. 8A and 8B are plan views illustrating a semiconductor memory device according to example embodiments of the present inventive concepts. FIG. 9 is a cross-sectional view, taken along the line I-I′ of FIGS. 8A and 8B, according to example embodiments of the present inventive concepts. For brevity of the description, discussions of those components of the semiconductor memory device that have been already discussed may be omitted.

Referring to FIGS. 8A, 8B and 9, each of the first and second string channel pillars SCP1 and SCP2 may include the string vertical channel section 222, the string vertical insulation layer 224, the string conductive pattern 226, and a gap-fill pattern 228. For example, the pad D may be in contact with the string vertical channel section 222 penetrating the first interlayer dielectric layer 172 and one of the first and second string select structures SLS1 and SLS2. The string vertical channel section 222 may be in contact with the pad D. For example, the string vertical channel section 222 may have a shape of hollow pipe, cylinder, or cup.

The string vertical insulation layer 224 may be disposed between the string vertical channel section 222 and one of the first and second string select lines SSL1 and SSL2, and extend in the vertical direction along the outer wall of the string vertical channel section 222. For example, the string vertical insulation layer 224 may surround the outer wall of the string vertical channel section 222. The string conductive pattern 226 may be disposed on the upper portion of the string vertical channel section 222. The gap-fill pattern 228 may be disposed in an inner space surrounded by the vertical channel section 222. The gap-fill pattern 228 may include an insulating material (e.g., a silicon oxide layer, a silicon nitride layer, etc.).

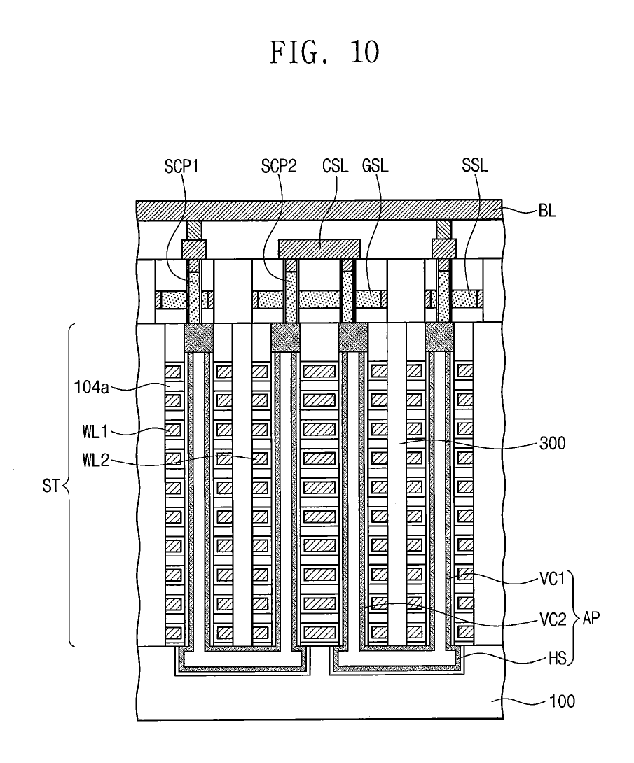

FIG. 10 is a cross-sectional view illustrating a semiconductor memory device according to example embodiments of the present inventive concepts. For brevity of the description, discussions of those components of the semiconductor memory device that have been already discussed may be omitted.

A plurality of the stack structures ST may be disposed on the substrate 100. Each of the stack structures ST may include electrodes and insulation patterns 104a that are alternately stacked on the substrate 100. In some embodiments, the stack structures ST may extend in one direction and a separation insulation layer 300 may be disposed between the stack structures ST. The separation insulation layer 300 may include an insulating material (e.g., a silicon oxide layer, a silicon nitride layer, etc.).

Each of active patterns AP may include vertical channel sections VC1 and VC2 that penetrate the stack structures ST and a horizontal section HS that connects the vertical channel sections VC1 and VC2 below the stack structures ST. The vertical channel sections VC1 and VC2 may be provided in vertical holes that penetrate the stack structures ST. The horizontal section HS may be provided in a horizontal recess region disposed in an upper portion of the substrate 100. One of the vertical channel sections VC1 and VC2 may be connected to the common source line CSL, and the other of the vertical channel sections VC1 and VC2 may be connected to the bit line BL. The horizontal section HS may be provided between the substrate 100 and the stack structures ST and thus may connect the vertical channel sections VC1 and VC2 to each other.

In more detail, in each of the active patterns AP, the vertical channel sections VC1 and VC2 may include a first vertical channel section VC1 penetrating first word lines WL1 and a second vertical channel section VC2 penetrating second word lines WL2. The first vertical channel section VC1 may be connected to the bit line BL, and the second vertical channel section VC2 may be connected to the common source line CSL. The horizontal section HS may extend from below the first word lines WL1 to below the second word lines WL2 so that the first channel section VC1 may be connected to the second vertical channel section VC2.

Each of the active patterns AP may include a semiconductor pattern that penetrates the stack structures ST and is electrically connected to the substrate 100. In the vertical channel sections VC1 and VC2, the semiconductor pattern may cover inner walls of vertical holes formed in the stack structures ST. In the horizontal section HS, the semiconductor pattern may cover an inner wall of the horizontal recess region formed in the substrate 100. The semiconductor pattern may include a semiconductor material.

The select lines GSL and SSL may be disposed on each of the stack structures ST. For example, the string select line SSL may vertically overlap the first vertical channel section VC1, and the ground select line GSL may vertically overlap the second vertical channel section VC2 as illustrated in FIG. 10. In other words, the first word lines WL1 may be disposed between the string select line SSL and the substrate 100, and the second word lines WL2 may be disposed between the ground select line GSL and the substrate 100. The ground select line GSL and the string select line SSL may be horizontally spaced apart from each other. Those discussed with reference to FIGS. 5A and 5B may be substantially identically applicable to the description on an arrangement relationship of the first and second vertical pillars VP1 and VP2, the string select line SSL, and the ground select line GSL, and thus the description thereof may be omitted. In this case, the string select line SSL shown in FIG. 10 may correspond to the first string select line SSL1 depicted in FIGS. 2A and 2B, and the ground select line GSL shown in FIG. 10 may correspond to the second string select line SSL2 depicted in FIGS. 2A and 2B.

The first string channel pillar SCP1 may penetrate the string select line SSL, and the second string channel pillar SCP2 may penetrate the ground select line GSL. The first string channel pillar SCP1 may be electrically connected to the first vertical channel section VC1, and the second string channel pillar SCP2 may be electrically connected to the second vertical channel section VC2. Those discussed with referent to FIGS. 5A and 5B may be substantially identically applicable to an arrangement relationship between the first and second string channel pillars SCP1 and SCP2, and thus a description thereof may be omitted. In this case, the first string channel pillar SCP1 shown in FIG. 10 may correspond to the first string channel pillar SCP1 depicted in FIGS. 5A and 5B, and the second string channel pillar SCP2 shown in FIG. 10 may correspond to the second string channel pillar SCP2 depicted in FIGS. 2A and 2B.

The bit line BL may be electrically connected to the first vertical channel section VC1 through the first string channel pillar SCP1, and the common source line CSL may be electrically connected to the second vertical channel section VC2 through the second string channel pillar SCP2.

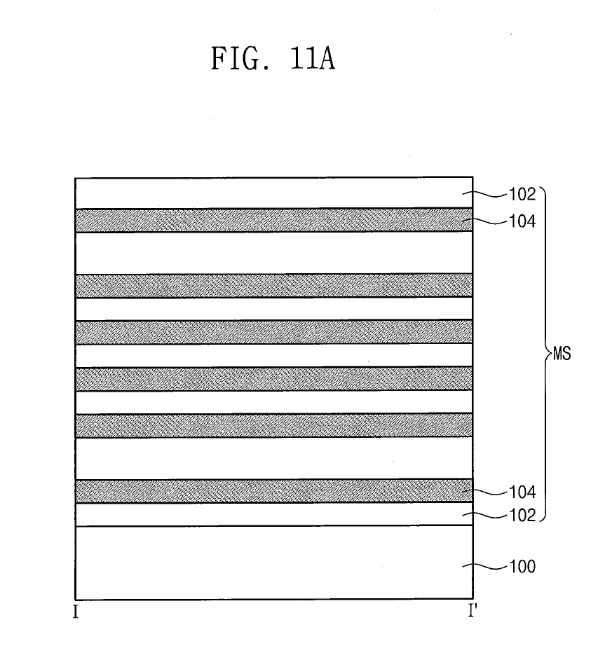

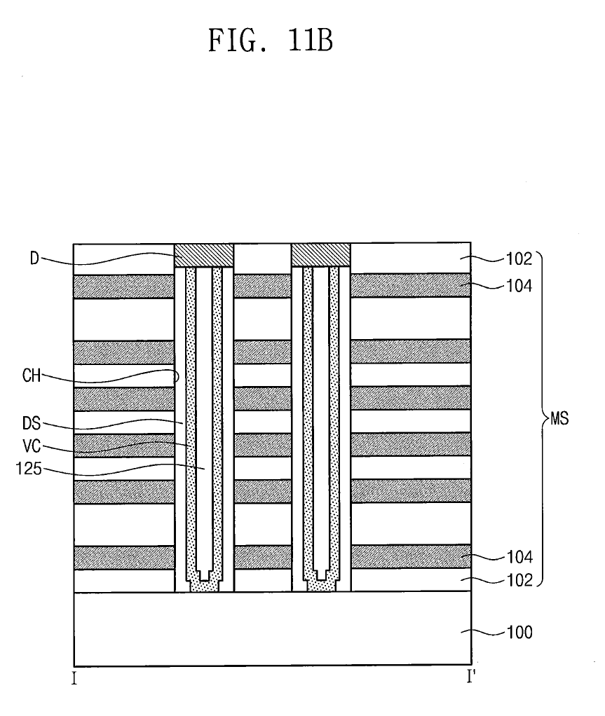

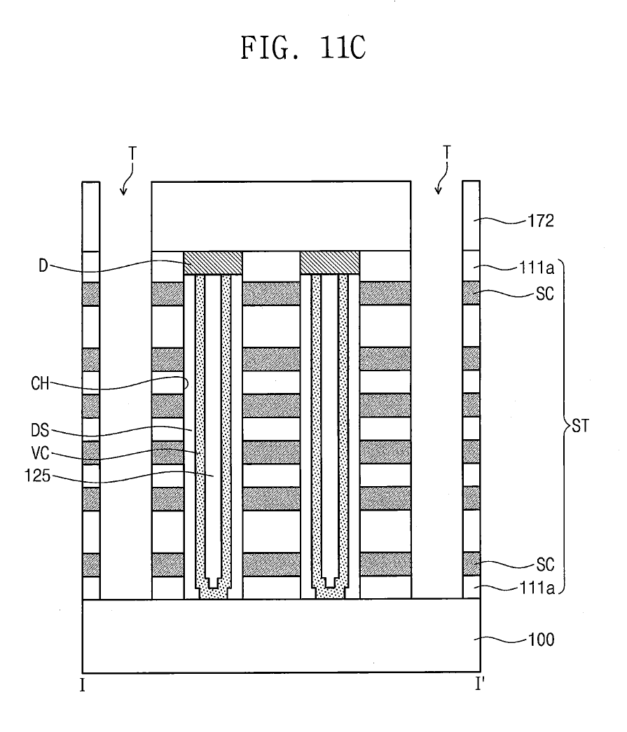

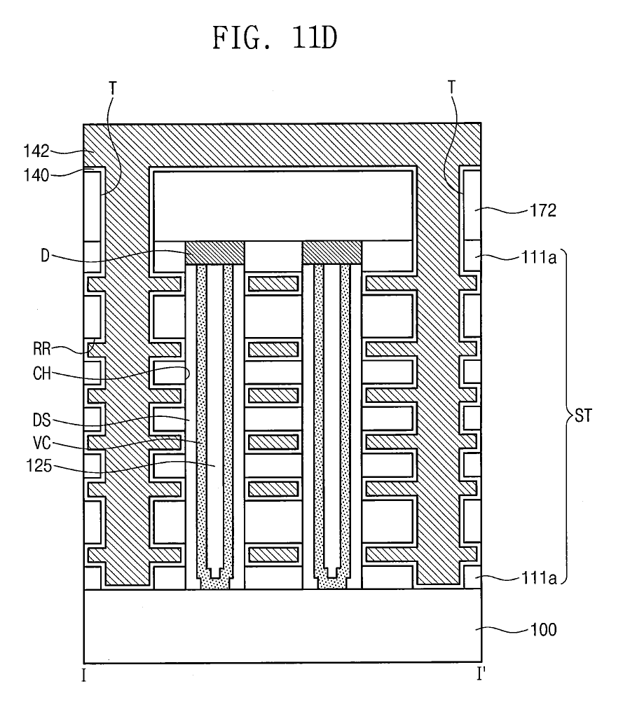

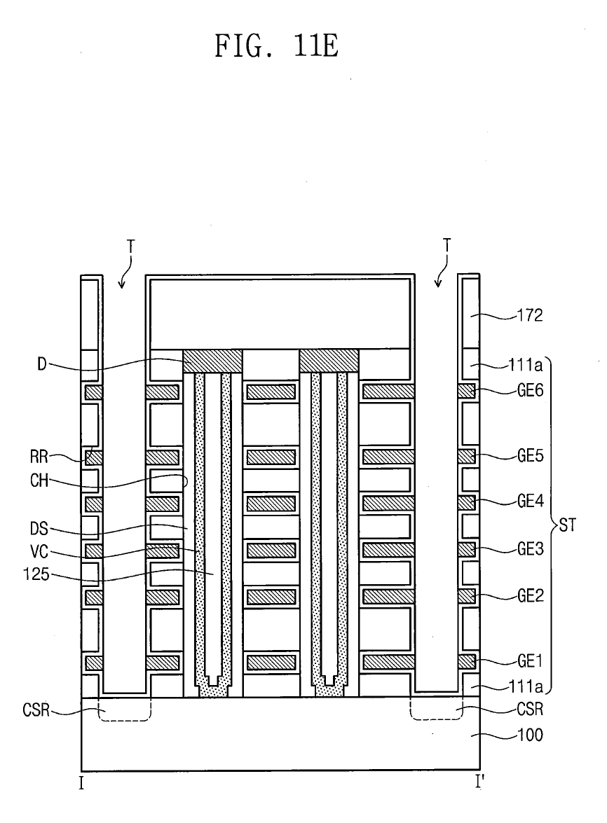

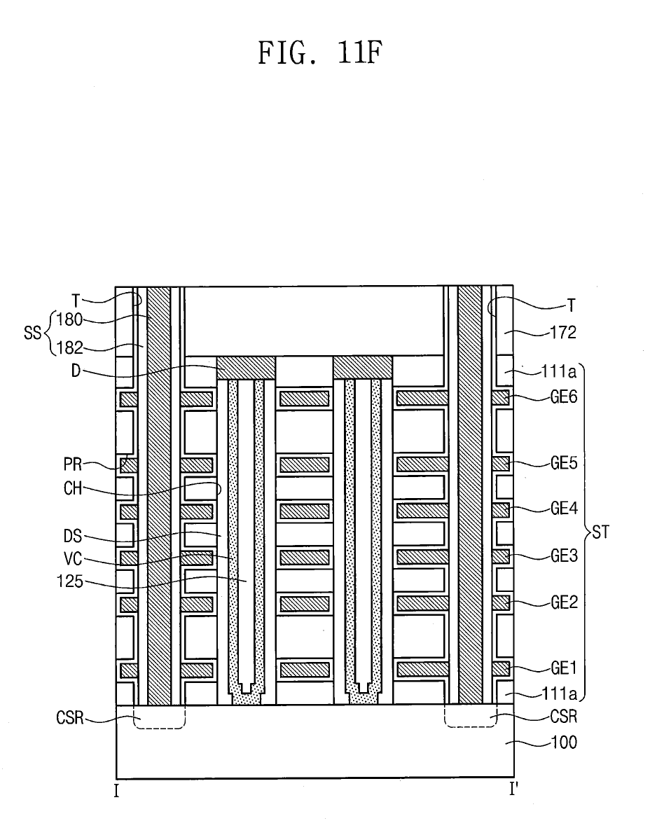

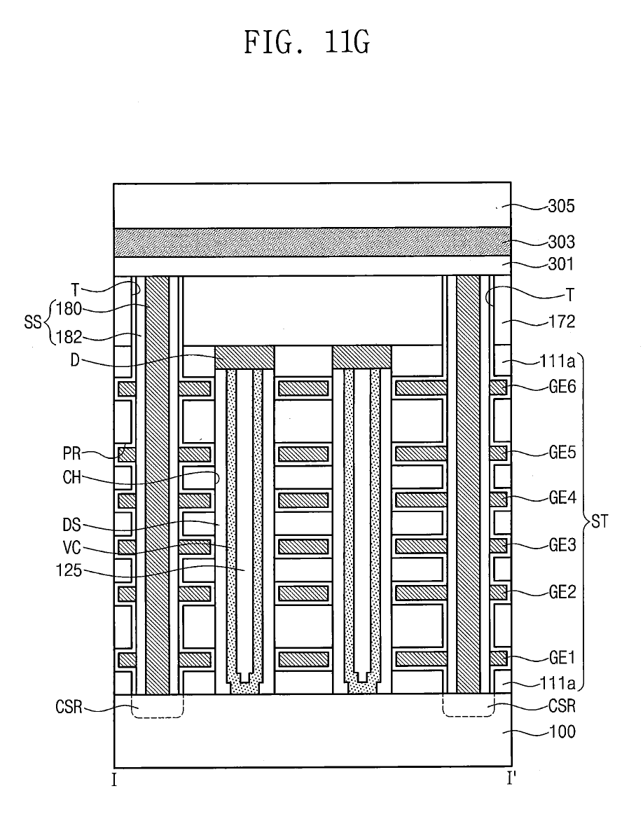

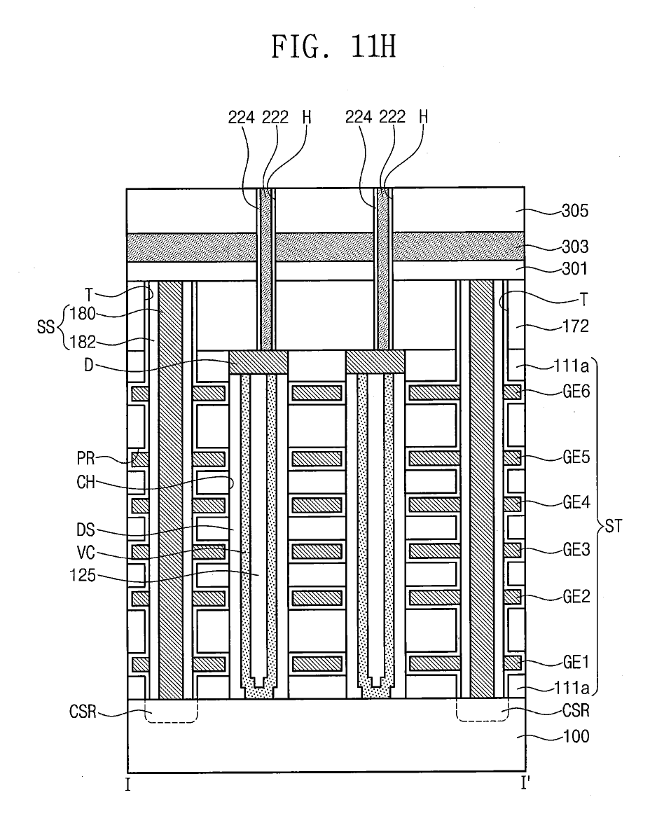

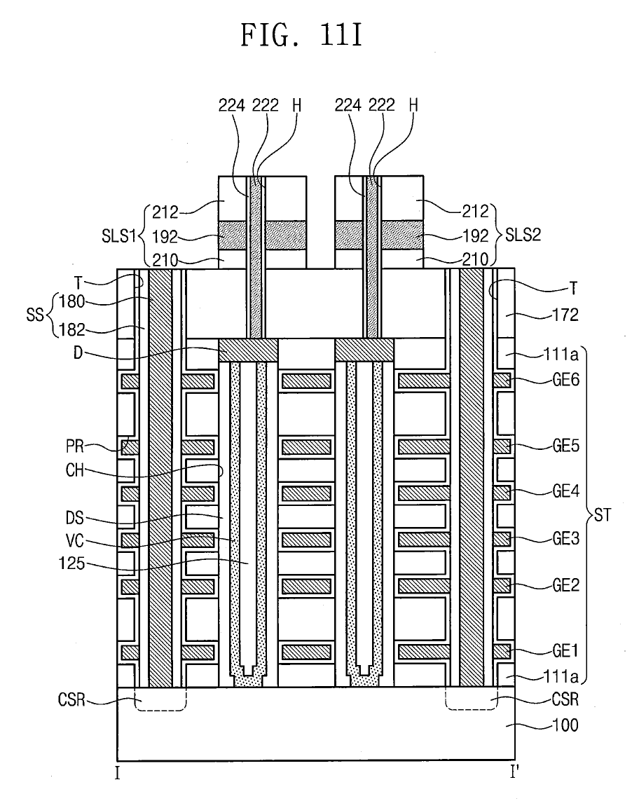

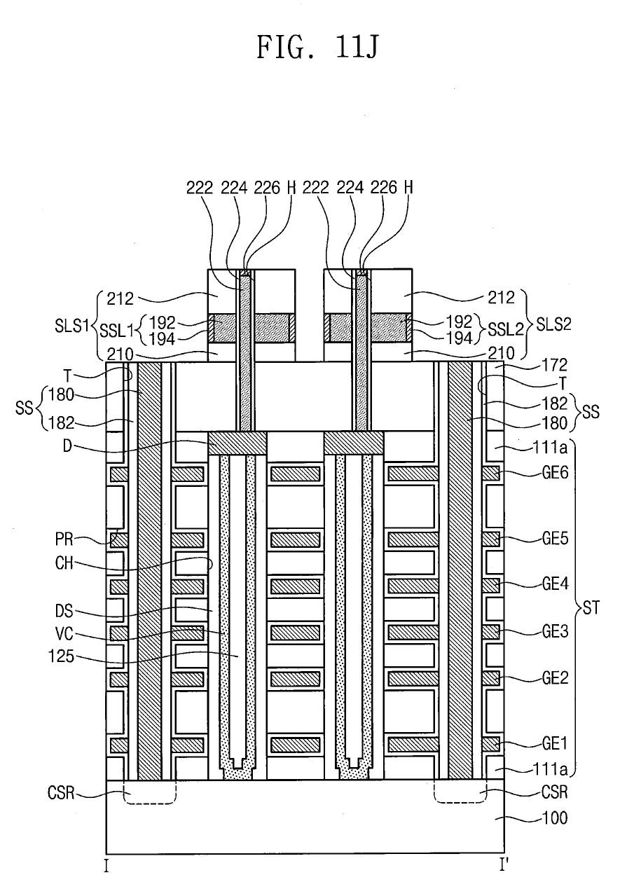

FIGS. 11A to 11J are cross-sectional views, taken along the line I-I′ of FIGS. 2A and 2B, illustrating a method of fabricating a semiconductor memory device according to example embodiments of the present inventive concepts.

Referring to FIG. 11A, a mold structure MS may be formed on a substrate 100. The substrate 100 may be a silicon substrate, a silicon-germanium substrate, a germanium substrate, or a single crystalline epitaxial layer grown on a single crystalline silicon substrate.

The mold structure MS may include insulation layers 102 and sacrificial layers 104 that are alternately and repeatedly stacked on the substrate 100. The insulation layers 102 may include a material having an etch selectivity with respect to the sacrificial layers 104. For example, the insulation layers 102 may include a silicon oxide layer, and the sacrificial layers 104 may include a silicon nitride layer or a silicon oxynitride layer. The insulation layers 102 may be formed of the same material, and the sacrificial layers 104 may be formed of the same but different material from the insulation layers 102. In some embodiments, a buffer insulation layer (not shown) may be provided between the substrate 100 and the mold structure MS.

Referring to FIG. 11B, the mold structure MS may be patterned to form channel holes CH through which the substrate 100 is exposed. In detail, a mask pattern (not shown) may be formed on an uppermost insulation layer 102, and then the mold structure MS may be anisotropically etched using the mask pattern as an etch mask. The anisotropic etch process may be performed to form the channel holes CH, each of which has a constant (i.e., uniform) width along its height from the substrate 100. In some embodiments, the anisotropic etch process may be performed to form the channel holes CH each having a variable (i.e., non-uniform) width along its height from the substrate 100. That is, the channel holes CH may have an inner sidewall inclined with respect to the substrate 100. An over-etch action may be carried out such that the substrate 100 may be etched to have a recessed top surface. The channel holes CH may have a shape of circle, ellipse or polygon, in a plan view.

A charge storage structure DS may be formed on a sidewall of each of the channel holes CH. The charge storage structure DS may cover the sidewall of the channel hole CH, and partially cover a top surface of the substrate 100 that is exposed through the channel hole CH. In detail, the formation of the charge storage structure DS may include forming first, second, and third insulation layers that sequentially cover the sidewall of the channel hole CH and performing a dry etch process to remove portions of the first to third insulation layers so as to partially expose the top surface of the substrate 100.

As shown in FIG. 4, the charge storage structure DS may include a blocking insulation layer BLL, a charge storage layer CTL, and a tunneling insulation layer TL that are sequentially formed on the sidewall of the channel hole CH. The blocking insulation layer BLL may include, for example, a silicon oxide layer or a high-k dielectric layer (e.g., Al2O3, HfO2, etc.); the charge storage layer CTL may include, for example, a silicon nitride layer; and the tunneling insulation layer TL may include, for example, a silicon oxynitride layer or a high-k dielectric layer (e.g., Al2O3, HfO2, etc.).

A vertical channel section VC may be formed in the channel hole CH in which the charge storage structure DS is formed. The vertical channel section VC may conformally cover an inner sidewall of the charge storage structure DS and the top surface of the substrate 100 exposed through the charge storage structure DS. The vertical channel section VC may include, for example, a semiconductor material. For example, the vertical channel section VC may be one of a polycrystalline silicon layer, an organic semiconductor layer, and carbon nanostructures.

A gap-fill layer 125 may be formed in an inner space surrounded by the vertical channel section VC. The gap-fill layer 125 may completely fill the channel hole CH. The gap-fill layer 125 may be formed using an spin-on-glass (SOG) technique. The gap-fill layer 125 may include an insulating material, for example, a silicon oxide layer and/or a silicon nitride layer. Prior to the formation of the gap-fill layer 125, a hydrogen annealing process may be further performed to heat treat the vertical channel section VC under a gas atmosphere including hydrogen or deuterium. This hydrogen annealing process may cure crystalline defects present in the vertical channel section VC.

A pad D may be formed on upper portions of the vertical channel section VC, the charge storage structure DS, and the gap-fill layer 125. The pad D may be formed by etching upper portions of the charge storage structure DS, the vertical channel section VC, and the gap-fill layer 125 to form a recess and then filling the recess with a conductive material. In some embodiments, the pad D may be formed by doping an upper portion of the vertical channel section VC with impurities having a different conductivity from the vertical channel section VC.

As shown in FIG. 6, before forming the charge storage structure DS, a semiconductor pillar SP may be formed in each of the channel holes CH. A selective epitaxial growth may be performed to grow the semiconductor pillar SP from the substrate 100 of which a portion exposed through the channel hole CH is used as a seed layer. The semiconductor pillar SP may include a material having the same conductivity as that of the substrate 100, for example, an intrinsic semiconductor or a p-type conductive semiconductor.

Referring to FIG. 11C, trenches T may be formed by performing an anisotropic etch process on the mold structure MS. The trenches T may be formed by forming a first interlayer dielectric layer 172 on the mold structure MS and anisotropically etching the mold structure MS using the first interlayer dielectric layer 172 as an etch mask until exposing the top surface of the substrate 100. The trenches T may be formed to extend in a second direction Y. The trenches T may then be formed to have a shape of line or rectangle extending in the second direction Y. As the trenches T are formed, a plurality of stack structures ST, that are spaced apart from each other in a first direction X may be formed on the substrate 100.

Each of the stack structures ST may include insulation patterns 111a and sacrificial patterns SC that are sequentially and alternately stacked on the substrate 100. The insulation patterns 111a may be formed by patterning the insulation layers 102, and the sacrificial patterns SC may be formed by pattering the sacrificial layers 104. The trenches T may expose sidewalls of the stack structure ST.

Referring to FIG. 11D, the sacrificial patterns SC exposed through the trenches T may be removed to form recess regions RR between the insulation patterns 111a that are spaced apart from each other in a vertical direction. The recess regions RR may be formed by performing a wet etch process and/or an isotropic dry etch process to remove the sacrificial patterns SC. Since the sacrificial patterns SC include a material having an etch selectivity with respect to the insulation patterns 111a, the insulation patterns 111a may not be removed when the sacrificial patterns SC are removed. For example, in case that the sacrificial patterns SC are a silicon nitride layer and the insulation patterns 111a are a silicon oxide layer, the etch process may be performed using an etchant including phosphoric acid.

The recess regions RR may horizontally extend from each of the trenches T into between the insulation patterns 111a. The recess regions RR may expose top and bottom surfaces of the insulation patterns 111a and a portion of an outer wall of the charge storage structure DS.

A horizontal insulation layer 140 may be formed to cover a top surface of the first interlayer dielectric layer 172 and surfaces of layers exposed through the recess regions RR and the trenches T. In detail, the horizontal insulation layer 140 may conformally cover surfaces of the insulation patterns 111a, the outer wall of the charge storage structure DS exposed through the recess regions RR, the top surface of the substrate 100, and the top surface of the first interlayer dielectric layer 172. The horizontal insulation layer 140 may be formed using a deposition process having a good step coverage. For example, the horizontal insulation layer 140 may be formed using a chemical vapor deposition (CVD) or an atomic layer deposition (ALD). The horizontal insulation layer 140 may include a silicon oxide layer (e.g., SiO₂) or a high-k dielectric layer (e.g., aluminum oxide (Al₂O₃), hafnium oxide (HfO₂), etc.).

A gate electrode layer 142 may be formed on the horizontal insulation layer 140. The gate electrode layer 142 may fill the trenches T and the recess regions RR. The gate electrode layer 142 may include a metallic material (e.g., tungsten).

Referring to FIG. 11E, the gate electrode layer 142 may be removed from inside the trenches T and thus first to sixth gate electrodes GE1 to GE6 may be formed in the recess regions RR. After the first to sixth gate electrodes GE1 to GE6 are formed, impurity regions CSR may be formed in the substrate 100 exposed through the trenches T. The impurity regions CSR may be formed by, for example, an ion implantation process. The impurity region CSR may have a different conductivity from the substrate 100.

Referring to FIG. 11F, separation structures SS may be formed in the trenches T. Each of the separation structures SS may include spacers 182 and a common source contact 180. The spacers 182 may cover sidewalls of each of the trenches T. In detail, the formation of the spacers 182 may include forming an insulation layer (not shown) covering the sidewalls and a bottom surface of the trench T and then etching a portion of the insulation layer (not shown) covering the bottom surface of the trench T.

When the portion of the insulation layer is removed, portions of the horizontal insulation layer 140 that are on the top surfaces of the substrate 100 and the first interlayer dielectric layer 172 may also be removed from. The etch process for forming the spacers 182 may thus reveal the top surface of the substrate 100 exposed through the trench T and further reveal the top surface of the first interlayer dielectric layer 172. The spacers 182 may include, for example, a silicon oxide layer or a silicon nitride layer.

The common source contact 180 may be formed by filling a remaining space of the trench T in which the spacers 182 are formed. The common source contact 180 may be formed performing, for example, a chemical vapor deposition (CVD), a physical vapor deposition (PVD), or an atomic layer deposition (ALD). The common source contact 180 may include at least one of, for example, metal (e.g., copper or aluminum), conductive metal nitride (e.g., titanium nitride or tantalum nitride), and transitional metal (e.g., titanium or tantalum).

Referring to FIG. 11G, a first insulation layer 301, a conductive layer 303, and a second insulation layer 305 may be sequentially formed on the first interlayer dielectric layer 172. The first insulation layer 301 may cover the top surface of the first interlayer dielectric layer 172 and top surfaces of the separation structures SS. The first insulation layer 301 may include an insulating material (e.g., a silicon oxide layer, a silicon nitride layer, etc.). The conductive layer 303 may cover a top surface of the first insulation layer 301. The conductive layer 303 may include, for example, a polysilicon layer. The second insulation layer 305 may cover a top surface of the conductive layer 303. The second insulation layer 305 may include an insulating material (e.g., a silicon oxide layer, a silicon nitride layer, etc.).

Referring to FIG. 11H, holes H may be formed by sequentially patterning the second insulation layer 305, the conductive layer 303, the first insulation layer 301, and the first interlayer dielectric layer 172. Each of the holes H may be formed on each of the pads D. The holes H may expose the pads D.

A string vertical insulation layer 224 and a string vertical channel section 222 may be formed in each of the holes H. The string vertical insulation layer 224 may be formed by forming an insulation layer (not shown) conformally covering an inner surface of the hole H and a top surface of the second insulation layer 305 and then etching to remove the insulation layer from on top surfaces of the pads D and the top surface of the second insulation layer 305. The etch process may thus expose the top surfaces of the pads D and the top surface of the second insulation layer 305. The string vertical insulation layer 224 may include, for example, a silicon oxide layer.

The string vertical channel section 222 may be formed in a remaining space of the hole H including the string vertical insulation 224 formed therein. The string vertical channel section 222 may be formed by forming a channel layer (not shown) filling the hole H and covering the top surface of the second insulation layer 305 and then performing a planarization process until exposing the top surface of the second insulation layer 305. The string vertical channel region 222 may be, for example, one of a polycrystalline silicon layer, an organic semiconductor layer, and carbon nanostructures.

Referring to FIG. 11I, the second insulation layer 305, the conductive layer 303, and the first insulation layer 301 may be patterned to form a first string select structure SLS1 and a second string select structure SLS2 on the first interlayer dielectric layer 172. As shown in FIGS. 2A and 2B, in a plan view, the first and second string select structures SLS1 and SLS2 may be formed to extend in the second direction Y and may be spaced apart from each other in the first direction X. Each of the first and second string select structures SLS1 and SLS2 may include a first insulation pattern 210, a first conductive pattern 192, and a second insulation pattern 212 that are sequentially stacked on the first interlayer dielectric layer 172. As shown in FIGS. 2A and 2B, in a plan view, each of the first and second string select structures SLS1 and SLS2 may be formed to vertically overlap a pair of the vertical channel sections VC adjacent to each other in the first direction X. As the first and second string select structures SLS1 and SLS2 are formed, the top surface of the separation structure SS may be exposed.

Referring to FIG. 11J, second conductive patterns 194 may be formed by performing, for example, a silicide process on side surfaces of the first conductive patterns 192 exposed through the first and second insulation patterns 210 and 212. The silicide process may include forming, on the first interlayer dielectric layer 172, a metal layer (e.g., cobalt (Co)) conformally covering the side surfaces of the first conductive pattern 192 and a top surface of the string vertical channel section 222, performing a heat treatment on the metal layer to diffuse a metal ion included in the metal layer into the first conductive pattern 192, and combining the metal ion with a silicon ion included in the first conductive pattern 192. For example, during the heat treatment, the metal ion included in the metal layer may diffuse into the string vertical channel section 222 in contact with the metal layer and thus a string conductive pattern 226 may be formed on an upper portion of the string vertical channel section 222. For example, the string conductive pattern 226 may include cobalt silicide (CoSi). The heat treatment may be, for example, a rapid thermal process (RTP) and may be performed at a temperature of about 700° C. or greater. The metal layer may be removed after the silicide process is performed.

The first conductive pattern 192 of the first string select structure SLS1 and the second conductive pattern 194 formed thereon may constitute a first string select line SSL1, and the first conductive pattern 192 of the second string select structure SLS2 and the second conductive pattern 194 formed thereon may constitute a second string select line SSL2. The formation of the second conductive pattern 194 may enhance electrical characteristics of the first and second string select structures SLS1 and SLS2.

Referring again to FIGS. 2A, 2B and 3, a second interlayer dielectric layer 200 may be formed on the first interlayer dielectric layer 172. The second interlayer dielectric layer 200 may be formed by forming an insulation layer (not shown) on the first interlayer dielectric layer 172 and then performing a planarization process until exposing a top surface of the second insulation pattern 212. The second interlayer dielectric layer 200 may fill a space between the first and second string select structures SLS1 and SLS2. The second interlayer dielectric layer 200 may cover a side surface of the second conductive pattern 194 and expose a top surface of the string conductive pattern 226. The second interlayer dielectric layer 200 may include an insulating material (e.g., a silicon oxide layer, a silicon nitride layer, etc.).

Bit lines BL may be formed on the second interlayer dielectric layer 200. Each of the bit lines BL may be formed to be electrically connected to one of a pair of the vertical pillars VP vertically overlapping the first string select structure SLS1 and one of a pair of the vertical pillars VP vertically overlapping the second string select structure SLS2. The bit lines BL may include a conductive material (e.g., copper, tungsten, etc.).

According to example embodiments of the present inventive concepts, a plurality of string select lines may be horizontally spaced apart from each other on the stack structure such that it may be possible to secure a patterning space between the first and second string select lines without limitation of the minimum spaced distance between the first and second vertical pillars. It thus may be advantageous to enhance the integration of semiconductor memory cells without increasing an area of the stack structure.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A semiconductor memory device comprising:
a stack structure including a plurality of word lines stacked on a substrate;
a plurality of first vertical pillars and a plurality of second vertical pillars that extend through the stack structure;
a first string select line overlapping the plurality of first vertical pillars in a plan view; and
a second string select line overlapping the plurality of second vertical pillars in the plan view and being spaced apart from the first string select line in a first direction,
wherein, in the plan view, a shortest distance between a side of one of the plurality of first vertical pillars and a side of one of the plurality of second vertical pillars that is closest to the one of the plurality of first vertical pillars is less than a shortest distance between a side of the first string select line and a side of the second string select line.

2. The semiconductor memory device of claim 1, further comprising:
a plurality of first string channel pillars that extend through the first string select line and are electrically connected to the plurality of first vertical pillars, respectively; and
a plurality of second string channel pillars that extend through the second string select line and are electrically connected to the plurality of second vertical pillars, respectively.

3. The semiconductor memory device of claim 2, wherein the plurality of first vertical pillars has a diameter that is greater than a diameter of the plurality of first string channel pillars, and
wherein the plurality of second vertical pillars has a diameter that is greater than a diameter of the plurality of second string channel pillars.

4. The semiconductor memory device of claim 2, wherein one of the plurality of first string channel pillars has a center that is offset from a center of a corresponding one of the plurality of first vertical pillars that overlaps the one of the plurality of first string channel pillars in the plan view, and
wherein one of the plurality of second string channel pillars has a center that is offset from a center of a corresponding one of the plurality of second vertical pillars that overlaps the one of the plurality of second string channel pillars in the plan view.

5. The semiconductor memory device of claim 2, wherein a distance between a center of the one of the plurality of first vertical pillars and a center of the one of the plurality of second vertical pillars is less than a distance between a center of one of the plurality of first string channel pillars and a center of one of the plurality of second string channel pillars that is closest to the one of the plurality of first string channel pillars.

6. The semiconductor memory device of claim 2, wherein a shortest distance between centers of first and second ones of the plurality of first string channel pillars that are adjacent each other is less than a distance between a center of one of the plurality of first string channel pillars and a center of one of the plurality of second string channel pillars that is closest to the one of the plurality of first string channel pillars.

7. The semiconductor memory device of claim 1, wherein each of the plurality of first channel pillars and the plurality of second string channel pillars comprises:
a string vertical channel section that extends through one of the first and second string select lines; and
a conductive pattern on an upper portion of the string vertical channel section,
wherein the string vertical channel section includes polysilicon and the conductive pattern includes metal silicide.

8. The semiconductor memory device of claim 1, wherein the one of the plurality of first vertical pillars comprises a first one of the plurality of first vertical pillars, and the one of the plurality of second vertical pillars comprises a first one of the plurality of second vertical pillars, and
wherein the semiconductor memory device further comprises a bit line that extends in the first direction, and the bit line is electrically connected to a second one of the plurality of first vertical pillars and a second one of the plurality of second vertical pillars.

9. The semiconductor memory device of claim 1, wherein, in the plan view, each of the first and second string select lines comprises protrusions and recesses that alternately arranged in a second direction that traverses the first direction.

10. The semiconductor memory device of claim 1, wherein each of the first and second string select lines has a straight line shape extending in a second direction that traverses the first direction.

11. The semiconductor memory device of claim 1, wherein each of the first and second string select lines comprises:
first patterns spaced apart from each other in the first direction; and
a second pattern between the first patterns,
wherein the first patterns include metal silicide and the second pattern includes polysilicon.

12. A semiconductor memory device comprising:
a stack structure including a plurality of word lines stacked on a substrate;
a plurality of first vertical pillars and a plurality of second vertical pillars that extend through the stack structure;
a first string select line overlapping the plurality of first vertical pillars in a plan view; and
a second string select line overlapping the plurality of second vertical pillars in the plan view and being horizontally spaced apart from the first string select line,
wherein, in the plan view, at least one of the plurality of first vertical pillars and the plurality of second vertical pillars is overlapped by an area between the first and second string select lines.

13. The semiconductor memory device of claim 12, wherein, in the plan view, a shortest distance between a side of the first string select line and a side of the second string select line is less than a shortest distance between a center of one of the plurality of first vertical pillars and a center of one of the plurality of second vertical pillars.

14. The semiconductor memory device of claim 12, further comprising:
a plurality of first string channel pillars that extend through the first string select line and are electrically connected to the plurality of first vertical pillars, respectively; and
a plurality of second string channel pillars that extend through the second string select line and are electrically connected to the plurality of second vertical pillars, respectively,
wherein a diameter of the plurality of first vertical pillars is greater than a diameter of the plurality of first string channel pillars, and
wherein a diameter of the plurality of second vertical pillars is greater than a diameter of the plurality of second string channel pillars.

15. The semiconductor memory device of claim 12, wherein the plurality of word lines include a metallic material and the first and second string select lines include polysilicon.

16. An integrated circuit device comprising:
a stack structure including a plurality of word lines stacked on a substrate;
a first vertical pillar extending through the stack structure;
a first string select line overlapping the first vertical pillar in a plan view and extending longitudinally in a first direction, the first string select line comprising a first sidewall and a second sidewall opposite the first sidewall, and the first vertical pillar being closer to the first sidewall of the first string select line than the second sidewall of the first string select line; and
a first string channel pillar extending through the first string select line and being electrically connected to the first vertical pillar,
wherein a center of the first string channel pillar is offset from a center of the first vertical pillar in a second direction traversing the first direction away from the first sidewall of the first string select line in the plan view.

17. The device of claim 16, wherein a width of the first string channel pillar in the second direction is less than a width of the first vertical pillar in the second direction.

18. The device of claim 16, wherein the first vertical pillar comprises a portion not overlapped by the first string select line in the plan view.

19. The device of claim 16, further comprising:
a second vertical pillar extending through the stack structure;
a second string select line overlapping the second vertical pillar in the plan view and extending longitudinally in the first direction, the second string select line comprising a first sidewall and a second sidewall opposite the first sidewall, and the second vertical pillar being closer to the first sidewall of the second string select line than the second sidewall of the second string select line; and
a second string channel pillar extending through the second string select line and being electrically connected to the second vertical pillar,
wherein a center of the second string channel pillar is offset from a center of the second vertical pillar in the second direction away from the first sidewall of the second string select line in the plan view, and
wherein the second string select line is spaced apart from the first string select line in the second direction.

20. The device of claim 19, wherein a shortest distance between one of the first and second sidewalls of the first string select line and one of the first and second sidewalls of the second string select line is greater than a shortest distance between a side of the first vertical pillar and a side of the second vertical pillar.
